(19) United States
(12) Patent Application Publication
(10) Pub. No.: US 2026/0331803 A1
(43) Pub. Date: Oct. 22, 2026

(54) ELECTROMECHANICAL ASSEMBLY AND CONTROL DEVICE

(71) Applicant: Robert Bosch GmbH, Stuttgart (DE)

(72) Inventor: Dieter Ludwig, Ludwigsburg (DE)

(21) Appl. No.: 19/113,218

(22) PCT Filed: Jan. 25, 2024
(86) PCT No.: PCT/EP2024/051776

§ 371 Date: Mar. 19, 2025

(30) Foreign Application Priority Data
Feb. 10, 2023 (DE) 10 2023 201 103.4

(51) Int. Cl. H01R 12/72; H01R 13/504; H01R 13/631; H01R 24/64; H01R 31/06

(52) U.S. Cl. CPC H01R 12/725; H01R 12/724; H01R 13/5045; H01R 13/631; H01R 24/64; H01R 31/06; H01R 2201/26

(57) ABSTRACT

An electromechanical assembly for a control device. The assembly includes a plug terminal strip which is made of plastic and includes a receiving opening formed in the plug terminal strip for receiving a plug module. The plug module includes a module housing which can be inserted into the receiving opening of the plug terminal strip in the direction of a longitudinal axis of the module housing up to an end position. The plug module includes at least one connection pin which is designed to contact a circuit board of the control device. The module housing includes a guide section with at least two lateral surfaces which are opposite one another in relation to the longitudinal axis and interact in a form-locking manner with countersurfaces formed in the receiving opening of the plug terminal strip.

### FIELD

The present invention relates to an electromechanical assembly for a control device, which is characterized by a particularly advantageous arrangement of a plug module, in particular in the form of a high-frequency interface, in the region of a plug terminal strip of the assembly. The present invention also relates to a control device comprising an electromechanical assembly configured according to the present invention.

### BACKGROUND INFORMATION

German Patent No. DE 102 56 374 B3 describes disposing a plug module comprising a two-part module housing in the region of a plug terminal strip. The two elements of the module housing are inserted from opposite sides of the plug terminal strip into a receiving opening of the plug terminal strip and latched to one another to fix the plug module to the plug terminal strip.

Germany Patent Application No. DE 10 2017 113 415 A1 describes disposing a press-in socket and a support sleeve in an adapter housing of a plug module, wherein said press-in socket and support sleeve can be pressed into the adapter housing.

Germany Patent No. DE 10 2009 023 292 B4 describes configuring the contact carrier in an electrical connector with a contact carrier from two contact carrier units which can be connected to one another and positioned in relation to one another via guide surfaces.

### SUMMARY

An electromechanical assembly according to the present invention for a control device may have an advantage that it is disposed in the receiving opening of a plug terminal strip in a particularly reliably or firmly fixed manner, which enables a relatively simple assembly process for configuring the assembly and the assembly comprises a small number of components. This also enables highly accurate positioning of the plug module in relation to the receiving opening in the plug terminal strip, and the at least one connection pin of the plug module in relation to a circuit board disposed in a control device, in order to ensure simple assembly or connection between the connection pin of the plug module and the circuit board.

In the light of the above explanations, it is therefore provided in an electromechanical assembly for a control device according to an example embodiment of the present invention that the assembly comprises a plug terminal strip which is made of plastic and comprises a receiving opening formed in the plug terminal strip for receiving a plug module, wherein the plug module comprises a module housing which can be inserted into the receiving opening of the plug terminal strip in the direction of a longitudinal axis of the module housing up to an end position, wherein the plug module comprises at least one connection pin which is designed to contact a circuit board of the control device, wherein the module housing comprises a guide section with at least two lateral surfaces which are opposite one another in relation to the longitudinal axis and interact in a form-locking manner with countersurfaces formed in the receiving opening of the plug terminal strip, and wherein the module housing in the region of the guide section on opposite sides outside the lateral surfaces comprises locking sections with elevations and/or depressions, which interact with depressions and/or elevations formed in the receiving opening outside the countersurfaces to create a force-locking connection in the end position of the module housing in the receiving opening of the plug connection strip.

Advantageous further developments of the electromechanical assembly according to the present invention for a control device are disclosed herein.

According to an example embodiment of the present invention, in a preferred structural design of the locking sections to minimize the cross-section of the guide region, it is provided that the locking sections are formed in the region of corner regions of the module housing which are disposed perpendicular to the longitudinal axis and to the plane of the lateral surfaces and extend in the direction of the longitudinal axis, and that the cross-section of the module housing in the region of the guide section, with the exception of the corner regions, is rectangular.

Forming four locking sections at the four corner regions of the guide section enables particularly secure and reliable locking or particularly high pull-out forces.

According to an example embodiment of the present invention, it is also preferable that, on the side facing away from a plug collar, the plug terminal strip comprises at least one extension which projects out of the receiving opening to form an axial stop for reaching the end position of the module housing in the receiving opening. This reliably limits the insertion path of the module housing when the module housing is mechanically inserted or pressed into the receiving opening, and also precisely positions the at least one connection pin in relation to the circuit board in longitudinal direction.

The process of pressing the module housing into the receiving opening can be optimized if the module housing and/or the receiving opening is/are at least partially conical when viewed in the direction of the longitudinal axis.

According to an example embodiment of the present invention, the module housing preferably comprises an opening which extends in the direction of the longitudinal axis for receiving a socket insert, wherein the at least one connection pin is received in the socket insert in a force-locking fixed manner, and wherein the socket insert is pressed into the opening.

The socket insert and/or the module housing can also comprise electromagnetic shielding in a conventional manner, in particular if the plug module is configured as an Ethernet connection.

According to an example embodiment of the present invention, in order to optimize the module housing with a view to easy insertion into the receiving opening and achieving the end position relative to the plug terminal strip, it is provided that, viewed in the direction of the longitudinal axis, the module housing comprises two additional sections on either side of the guide section, wherein the additional section facing the plug terminal strip has a smaller cross-sectional area and the other additional section has a larger cross-sectional area than the guide section.

The present invention furthermore also includes a control device, in particular for motor vehicle applications, comprising an electromechanical assembly configured according to the present invention as described thus far.

Further advantages, features and details of the present invention will emerge from the following description of a preferred example embodiment of the present invention and with reference to the figures.

### BRIEF DESCRIPTION OF THE DRAWINGS

FIG. 1 shows a control device in a perspective view, according to an example embodiment of the present invention.

FIG. 2 shows a subregion of the control device of FIG. 1 in the region of a plug terminal strip on the side facing an interior of the control device in a perspective view, according to an example embodiment of the present invention.

FIG. 3 shows a module housing of a plug module in a perspective view, according to an example embodiment of the present invention.

FIG. 4 shows a subsection of the plug terminal strip with a plug module inserted in a receiving opening in a cross-section, according to an example embodiment of the present invention.

FIG. 5 shows a longitudinal section in the region of the receiving opening in the plug terminal strip with the plug module disposed therein, according to an example embodiment of the present invention.

### DETAILED DESCRIPTION OF EXAMPLE EMBODIMENTS

The same elements or elements having the same function are provided with the same reference numbers in the figures.

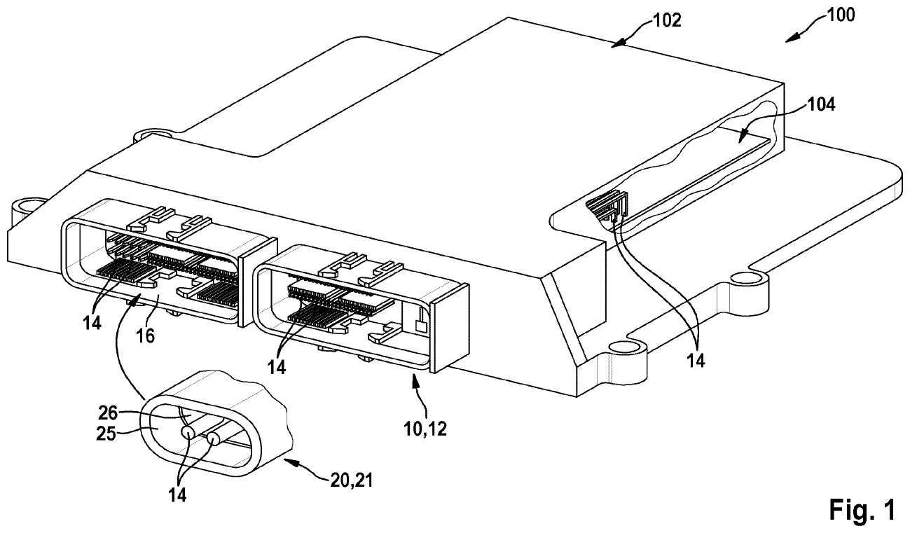

FIG. 1 shows a control device 100, as it can in particular, but not restrictively, be used for motor vehicle applications. When used in a semi-autonomous or autonomous vehicle, the control device 100 is used to acquire sensor data, for instance, and process said data to control drive elements or similar components of the motor vehicle.

The control device 100 comprises a housing 102, which is typically configured in at least two parts and is made of either plastic and/or metal, for example of sheet metal parts which are formed in a non-cutting manner and mechanically processed or aluminum die cast components. A plug terminal strip 12 is disposed with the housing 102 on one end face of the housing 102 as part of an electromechanical assembly 10. The control device 100 is electrically connected via the electromechanical assembly 10, in particular to a not depicted wiring harness of the motor vehicle.

In addition, at least one circuit board 104 or similarly configured circuit carrier, which is shown only in regions, is disposed within the housing 102 and comprises electronic components or an electronic circuit in a conventional manner. The circuit board 104 is brought into electrical contact with the electromechanical assembly 10 by electrically connecting a plurality of connection pins 14 disposed in the region of the plug terminal strip 12 to the circuit board 104, for example by means of solder connections or press-fit connections.

The plug terminal strip 12 is configured as an injection-molded part made of plastic and, for example, comprises two circumferential plug collars 16, via which the not depicted (wiring harness-side) plugs can be connected to the control device 100. The connection pins 14 are moreover disposed in a conventional manner within the cross-section of the plug collar 16 in order to be brought into contact with the wiring harness-side plugs. A plug module 20 is also disposed in the plug terminal strip 12 within the cross-section of the one plug collar 16 and is connected to it. The plug module 20 is used for data transmission and is configured as a high-frequency interface in the form of an Ethernet connection 21.

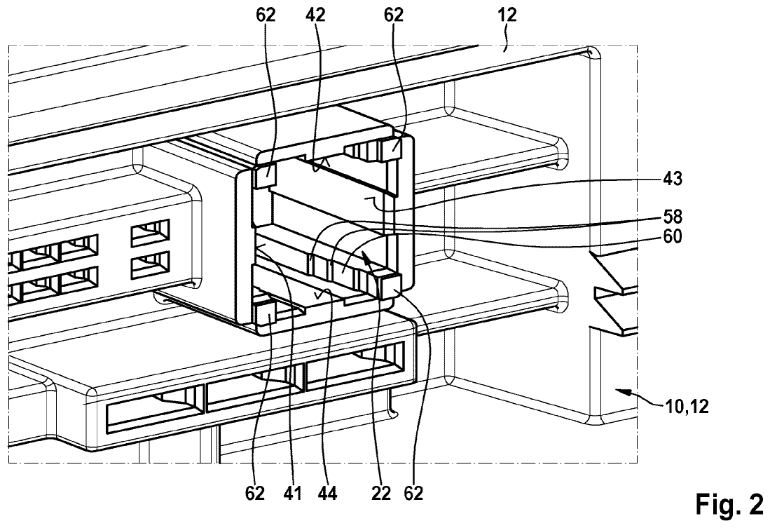

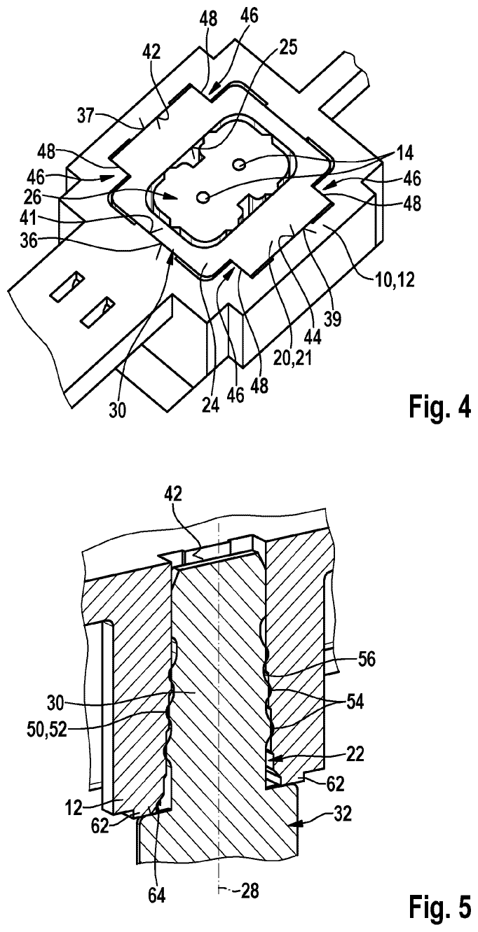

To receive the plug module 20, the plug terminal strip 12 comprises a receiving opening 22, as can best be seen from FIGS. 2 and 4. The plug module 20 comprises a module housing 24 which is made of plastic and comprises an opening 25, wherein a socket insert 26 is inserted or pressed into the opening 25 and said socket insert encloses two connection pins 14 in a force-locking manner that are typically bent at a right angle in the region of the interior space of the housing 102 and connected to the circuit board 104.

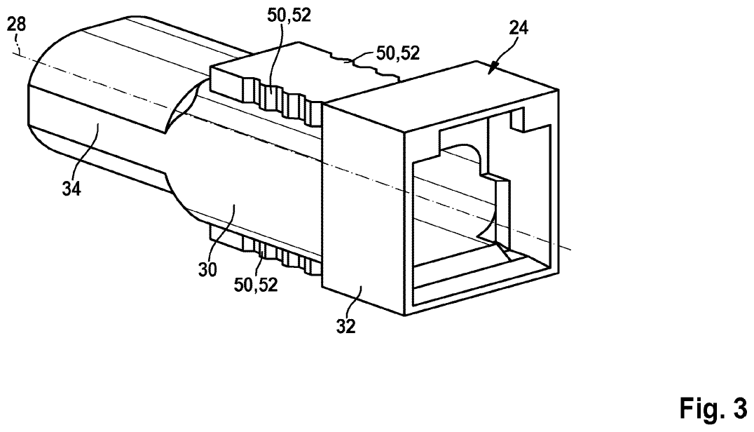

The module housing 24 shown by itself in FIG. 3 has a longitudinal axis 28 along which the module housing 24 or the plug module 20 can be inserted, in particular pressed, into the receiving opening 22 of the plug terminal strip 12 until an end position is reached. Viewed in the direction of the longitudinal axis 28, the module housing 24 comprises a guide section 30 in an approximately central region, wherein two additional sections 32, 34 are disposed on opposite sides of the guide section 30 in the direction of the longitudinal axis 28. The one additional section 32 is disposed such that it is oriented in the direction of the interior of the housing 102 and has a larger cross-section or cross-sectional area than the guide section 30, while the other additional section 34 is disposed in the region inside the plug collar 16, i.e. on the side facing away from the interior of the housing 102, and has a cross-section or a cross-sectional area that is smaller than that of the guide section 30 and the receiving opening 22 in order to push the module housing 24 into the receiving opening 22 by inserting the other additional section 34.

The guide section 30 is approximately rectangular or square in the direction of its cross-section which extends perpendicular to the longitudinal axis 28 and has four lateral surfaces 36 to 39 that interact in a form-locking manner with subsections comprising countersurfaces 41 to 44 configured in the receiving opening 22 (FIG. 4). Cutouts 48, which are rectangular in cross-section and extend in the direction of the longitudinal axis 28, are disposed in each of the four corner regions 46 of the cross-section of the guide section 30. The cutouts 48 comprise side wall sections 50 that extend parallel to the lateral surfaces 36 and 38 and are configured at least partially as locking sections 52 (FIGS. 3 and 5).

As can be seen in particular when considering FIGS. 3 and 5 together, the locking sections 52 comprise multiple elevations 54 and/or depressions 56 which, viewed in the direction of the longitudinal axis 28, are disposed one behind the other. When the module housing 24 is installed, the elevations 54 and/or depressions 56 interact with mirror-inverted depressions 58 and/or elevations 60 configured in the receiving opening 22 (FIG. 5) in order to create a force-locking connection. As can also be seen from FIG. 5, the lateral surfaces 36 to 39 of the module housing 24 have a width B that is greater than the width b of the countersurfaces 41 to 44 in the region of the receiving opening 22.

It must also be mentioned that the elevations 54 and/or depressions 56 on the module housing 24 and/or the depressions 58 and/or elevations 60 in the receiving opening 22 can also be configured in the form of barbs or similar geometries. The plastic material of the module housing 24 and the plug terminal strip 12 can also be different, in particular have different hardnesses from one another, for instance so that, when it forms the force-locking connection with the plug terminal strip 12, the module housing 24 deforms less than the plug terminal strip 12 or not at all. It can moreover be provided that the receiving opening 22 and/or the module housing 24 are/is conical when viewed in the direction of the longitudinal axis 28, at least in the region of the locking sections 52, such that the cross-section of said elements tapers in the direction of the plug collar 16. This makes it possible to influence the required pressing force of the module housing 24 into the receiving opening 22, in particular such that the (full) pressing force only has to be applied immediately before the axial end position of the module housing 24 in the receiving opening 22 is reached. Such a conicity can furthermore also make it easier to remove the plug terminal strip 12 or the module housing from an injection molding tool.

From FIGS. 2 and 5, it can also be seen that four extensions 62 project out of the receiving opening 22 in the region of the receiving opening 22 on the side facing away from the plug collar 16. When the module housing 24 is pressed into the receiving opening 22, the extensions 62 that are formed by extending the depressions 58 and the elevations 60 of the receiving opening 22 form an axial stop for reaching the (axial) end position of the module housing 24 in the plug terminal strip 12 because the section 32 rests against the extensions 62 with its end face 64 that extends perpendicular to the longitudinal axis 28 (FIG. 5).

To install the plug module 20 or the module housing 24, the module housing 24 is pushed or pressed in the direction of the longitudinal axis 28 into the receiving opening 22 of the plug terminal strip 12 up to the end position shown in FIG. 5. The elevations 54 and/or depressions 56 of the locking sections 52 engage with the depressions 58 and/or elevations 60 in the receiving opening 22.

The electromechanical assembly 10 described thus far can be altered or modified in a variety of ways without departing from the concept of the present invention.

1-10. (canceled)

11. An electromechanical assembly for a control device, comprising:
a plug terminal strip which is made of plastic and includes a receiving opening formed in the plug terminal strip configured to receive a plug module, wherein the plug module includes a module housing which can be inserted into the receiving opening of the plug terminal strip in a direction of a longitudinal axis of the module housing up to an end position, wherein the plug module includes at least one connection pin which is configured to contact a circuit board of the control device, wherein the module housing includes a guide section with at least two lateral surfaces which are opposite one another in relation to the longitudinal axis and interact in a form-locking manner with countersurfaces formed in the receiving opening of the plug terminal strip, and wherein the module housing in the region of the guide section on opposite sides outside the lateral surfaces includes locking sections with elevations and/or depressions, which interact with depressions and/or elevations formed in the receiving opening outside the countersurfaces to create a force-locking connection in the end position of the module housing in the receiving opening of the plug connection strip.

12. The assembly according to claim 11, wherein the locking sections are formed in a region of corner regions of the module housing which are disposed perpendicular to the longitudinal axis and to a plane of the lateral surfaces and extend in the direction of the longitudinal axis, and a cross-section of the module housing in a region of the guide section, with the exception of the corner regions, is rectangular.

13. The assembly according to claim 12, wherein four locking sections are formed at four corner regions of the guide section.

14. The assembly according to claim 11, wherein, on a side facing away from a plug collar, the plug terminal strip includes at least one extension which projects out of the receiving opening to form an axial stop for reaching the end position of the module housing in the receiving opening.

15. The assembly according to claim 14, wherein the at least one extension is formed by extending the depressions and/or elevations in the receiving opening.

16. The assembly according to claim 11, wherein the module housing and/or the receiving opening is at least partially conical when viewed in the direction of the longitudinal axis.

17. The assembly according to claim 11, wherein the module housing includes an opening which extends in the direction of the longitudinal axis configured to receive a socket insert, wherein the at least one connection pin is received in the socket insert in a force-locking fixed manner, and wherein the socket insert is pressed into the opening.

18. The assembly according to claim 11, wherein, viewed in the direction of the longitudinal axis, the module housing includes two additional sections on either side of the guide section, wherein an additional section of the additional section, facing the plug terminal strip, has a smaller cross-sectional area and the other additional section of the additional sections has a larger cross-sectional area than the guide section.

19. The assembly according to claim 11, wherein the plug module is configured as an Ethernet connection.

20. A control device, comprising:
an electromechanical assembly for the control device, including:
a plug terminal strip which is made of plastic and includes a receiving opening formed in the plug terminal strip configured to receive a plug module, wherein the plug module includes a module housing which can be inserted into the receiving opening of the plug terminal strip in a direction of a longitudinal axis of the module housing up to an end position, wherein the plug module includes at least one connection pin which is configured to contact a circuit board of the control device, wherein the module housing includes a guide section with at least two lateral surfaces which are opposite one another in relation to the longitudinal axis and interact in a form-locking manner with countersurfaces formed in the receiving opening of the plug terminal strip, and wherein the module housing in the region of the guide section on opposite sides outside the lateral surfaces includes locking sections with elevations and/or depressions, which interact with depressions and/or elevations formed in the receiving opening outside the countersurfaces to create a force-locking connection in the end position of the module housing in the receiving opening of the plug connection strip.
